(19) United States
(12) Patent Application Publication
(10) Pub. No.: US 2010/0258430 A1
(43) Pub. Date: Oct. 14, 2010

(54) SPUTTERING APPARATUS AND FILM FORMING METHOD

(75) Inventor: Yukio Kikuchi, Chigasaki-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignee: ULVAC, INC., Chigasaki-shi (JP)

(21) Appl. No.: 12/744,528

(22) PCT Filed: Nov. 26, 2008
(86) PCT No.: PCT/JP2008/071474

§ 371 Date: May 25, 2010

(30) Foreign Application Priority Data
Nov. 28, 2007 (JP) 2007-307817

(51) Int. Cl. C23C 14/35

(52) U.S. Cl. 204/192.1; 204/298.18

(57) ABSTRACT

A sputtering apparatus forming a film on a surface of a substrate, including: a table on which the substrate is placed; a plurality of targets disposed so that center axes thereof incline with respect to a normal line of the substrate placed on the table; and a plurality of magnetic field applying devices disposed between the targets and the substrate so as to surround the substrate, wherein the magnetic field applying devices generates a magnetic field, which has a horizontal magnetic field component parallel to the surface of the substrate, above the peripheral edge of the substrate.

### TECHNICAL FIELD

The present invention relates to a sputtering apparatus and a film forming method. Priority is claimed on Japanese Patent Application No. 2007-307817, filed Nov. 28, 2007, the content of which is incorporated herein by reference.

### BACKGROUND ART OF THE INVENTION

A sputtering apparatus has been widely used as a film forming apparatus which is suitable for forming films of semiconductor devices such as tunneling magnetic resistive (TMR) devices constituting an MRAM (Magnetic Random Access Memory).

In an example of the sputtering apparatus, a table mounted with a substrate and plural targets inclined with respect to the normal direction of the substrate are disposed in a process chamber. In such a sputtering apparatus, a sputter process is performed while rotating the table, so as to obtain an excellent film thickness distribution.

The MRAM which has been developed includes tunnel junction elements formed of a TMR film.

FIG. 4A is a sectional view of a tunnel junction element. As shown in FIG. 4A, the tunnel junction element 10 is formed by stacking a magnetic layer (fixed layer) 14, a tunnel barrier layer (insulating layer) 15, and a magnetic layer (free layer) 16. The tunnel barrier layer 15 is formed of an electric insulating material such as MgO.

Here, at the time of forming the tunnel barrier layer 15 such as an MgO film, oxygen ions are generated in plasma from oxygen atoms included in a target or oxygen gas supplied at the time of sputtering and the generated oxygen ions are accelerated with a target potential and are incident on a substrate. When charged particles such as electrons or oxygen ions are incident on a substrate, the crystal orientation of the tunnel barrier layer 15 is damaged and thus the resistance of the tunnel barrier layer 15 increases, thereby causing a problem in that the film characteristics are deteriorated.

Accordingly, it is important to reduce damage by reducing the charged particles incident on the tunnel barrier layer 15 or the substrate.

Therefore, for example, Patent Citation 1 discloses a film forming apparatus in which two permanent magnets are disposed between a target and a substrate with the substrate interposed therebetween. According to this configuration, the flight direction of the charged particles flying toward the substrate are deflected by forming a deflecting magnetic field in the vicinity of the substrate by the use of the permanent magnets, thereby suppressing the charged particles from entering a film-formed surface.

[Patent Citation 1] Japanese Unexamined Patent Application, First Publication No. 2000-313958

### DISCLOSURE OF THE INVENTION

### Problems to be Solved by the Invention

As described above, in the sputtering apparatus forming a film using multiple targets while rotating a substrate, an excellent film thickness uniformity can be obtained. However, there is a problem in that a variation in film resistance due to different film characteristics of a surface occurs on the surface of the substrate.

Specifically, in a region in the vicinity of an intersection between the axial direction of a target and the surface of the substrate, that is, in the peripheral edge of the substrate, since the flight distance of the charged particles incident from the vicinity of the target is smaller and the incidence angle on the surface of the substrate is smaller in comparison with the other parts, the energy of the incident charged particles is large. Accordingly, the damage on the crystal orientation of the tunnel barrier layer 15 locally increases, thereby enhancing the resistance of the tunnel barrier layer 15.

On the other hand, as it goes from the peripheral edge of the substrate to the center thereof, the flight distance of the charged particles incident from the vicinity of the target and the incidence angle on the surface of the substrate increase, whereby the energy of the incident charged particles decreases. Accordingly, the damage to the crystal orientation of the tunnel barrier layer 15 decreases and thus the resistance of the tunnel barrier layer 15 becomes smaller than that of the peripheral edge of the substrate. As a result, a variation in resistance uniformity is caused on the surface of the substrate, thereby deteriorating the uniformity in the film characteristic distribution of the substrate.

In the configuration in which permanent magnets are disposed with the substrate interposed therebetween as described in Patent Citation 1, since a part with a strong magnetic field and a part with a weak magnetic field exist in the peripheral edge of the substrate, it is not possible to uniformly deflect the charged particles incident on the substrate. Accordingly, the variation in resistance cannot be eliminated.

Particularly, in a large-sized substrate with a diameter of 200 mm or more, it is very difficult to obtain an excellent film characteristic uniformity.

The present invention is contrived to solve the above-mentioned problem. An object of the present invention is to provide a sputtering apparatus and a film forming method, which can improve the film characteristic by uniformly suppressing the incidence of the charged particles on the substrate over the entire substrate at the time of forming a film using a sputtering method.

### Means for Solving the Problem

In order to achieve the above-mentioned object, the present invention adopts the following. In particular, a sputtering apparatus according to the present invention is a sputtering apparatus forming a film on a surface of a substrate and includes: a table on which the substrate is placed; a plurality of targets disposed so that center axes thereof incline with respect to a normal line of the substrate placed on the table; and a plurality of magnetic field applying devices disposed between the targets and the substrate so as to surround the substrate, wherein the magnetic field applying devices generates a magnetic field, which has a horizontal magnetic field component parallel to the surface of the substrate, above the peripheral edge of the substrate.

It may be arranged such that the number of the magnetic field applying devices is three or more.

According to the sputtering apparatus, the magnetic field having a horizontal magnetic field component parallel to the surface of the substrate is generated above the substrate by the plurality of magnetic field applying devices disposed to surround the substrate placed on the table. Accordingly, charged particles generated in plasma are influenced by the Lorentz force from the generated magnetic field and are thus deflected in a direction perpendicular to the flight direction of the charged particles and the direction of magnetic field. Particularly, since a strong magnetic field is generated above the peripheral edge of the substrate, it is possible to suppress the incidence of the charged particles on the peripheral edge of the substrate in which the energy of the charged particles is greater than those of the other portions. Accordingly, since it is possible to reduce the damage to the substrate or the film on the substrate, and thus the resistance value of the film forming material can be suppressed from increasing. As a result, since the incidence of the charged particles on the substrate is suppressed uniformly over the entire substrate at the time of forming the film using the sputtering method, it is possible to improve the film characteristics of the film forming material formed on the substrate.

It may be arranged such that the sputtering apparatus further includes a rotation mechanism rotating the table about a rotation axis parallel to the normal line of the substrate placed on the table.

In this case, since the film forming process can be performed while rotating the substrate in a plane parallel to the surface of the substrate by the use of the rotation mechanism, it is possible to uniformly form a film on the entire surface of the substrate. As a result, it is possible to obtain an excellent film thickness uniformity. Since the magnetic field by the magnetic field applying devices can be uniformly applied to the peripheral edge of the substrate, it is possible to suppress the damage to the substrate or the film on the substrate in the entire process of forming the tunnel barrier layer as well as in the initial growth process of the tunnel barrier layer formed of MgO or the like as the underlying layer of the tunnel junction element. As a result, it is possible to maintain the film characteristics such as crystalline properties of a very thin tunnel barrier layer with a thickness of several A to 20 Å in the entire film forming process.

It may be arranged such that the number of the magnetic field applying devices is an even number greater than or equal to four, and the magnetic field applying devices are arranged so that the polarities of the adjacent magnetic field applying devices close to the substrate are different from each other.

In this case, the magnetic field is generated above the substrate by the magnetic field applying devices disposed to surround the substrate. Accordingly, charged particles generated in plasma are influenced by the Lorentz force from the generated magnetic field and are thus deflected in a direction perpendicular to the flight direction of the charged particles and the direction of the magnetic field.

Particularly, by providing an even number of four or more magnetic field applying devices, it is possible to generate a magnetic field to completely surround the peripheral edge of the substrate. Accordingly, since a strong magnetic field is generated above the peripheral edge of the substrate, it is possible to suppress the incidence of the charged particles on the peripheral edge of the substrate in which the energy of the charged particles is greater than those of the other portions. Accordingly, it is possible to reduce the damage to the substrate or the film on the substrate, and thus the tunnel resistance value of a TMR film formed of MgO as an insulating material can be suppressed from increasing. As a result, since the incidence of the charged particles on the substrate is suppressed uniformly over the entire substrate at the time of forming the film using the sputtering method in the entire process of forming the tunnel barrier layer, it is possible to improve the film characteristics of the film forming material formed on the substrate.

It may be arranged such that the magnetic field applying devices and the targets are disposed at the same angular positions in the peripheral direction of the substrate.

In this case, since the magnetic field applying devices and the targets are disposed at the same angular positions in the peripheral direction of the substrate, it is possible to generate a stronger magnetic field in a region in which the energy of the charged particles incident on the substrate is great and to generate a weaker magnetic field in a region in which the energy is small. Accordingly, it is possible to uniformly deflect the charged particles incident on the substrate. As a result, since the incidence of the charged particles on the substrate is uniformly suppressed over the entire substrate, it is possible to improve the film characteristic.

It may be arranged such that each target contains MgO as a film forming material.

In this case, as described above, since the incidence electrons or oxygen ions generated in plasma on the surface of the substrate can be prevented to reduce the damage to the substrate or the film of the substrate, it is possible to form an insulating film with a high crystal orientation on the entire surface of the substrate.

It may be arranged such that the sputtering apparatus further includes: a sputtering chamber in which the table and the targets are arranged; a vacuum exhaust device exhausting the sputtering chamber in vacuum; a gas supply device supplying sputtering gas to the sputtering chamber; and a power supply applying a voltage to the targets.

In this case, the sputtering chamber is made to be in vacuum by the vacuum exhaust device, the sputtering gas is introduced into the sputtering chamber from the gas supply device, and a voltage is applied to the targets from the power supply, whereby plasma is generated. Then, the ions of the sputtering gas collide with the targets being a cathode, and the atoms of the film forming material are popped out from the targets and are attached to the substrate. Accordingly, it is possible to form a film on the surface of the substrate.

On the other hand, a film forming method according to the present invention is a film forming method using a sputtering apparatus including: a table on which a substrate is placed; a plurality of targets disposed so that center axes thereof incline with respect to a normal line of the substrate placed on the table; and a plurality of magnetic field applying devices disposed between the targets and the substrate so as to surround the substrate, wherein a film forming process is performed on the surface of the substrate while applying a magnetic field, which has a horizontal magnetic field component parallel to the surface of the substrate, above the peripheral edge of the substrate.

It may be arranged such that the sputtering apparatus includes three or more magnetic field applying devices.

According to the film forming method, the magnetic field having a horizontal magnetic field component parallel to the surface of the substrate is generated above the substrate by the plurality of magnetic field applying devices disposed to surround the substrate placed on the table. Accordingly, charged particles generated in plasma are influenced by the Lorentz force from the generated magnetic field and are thus deflected in a direction perpendicular to the flight direction of the charged particles and the direction of the magnetic field. Particularly, since a strong magnetic field is generated above the peripheral edge of the substrate, it is possible to suppress the incidence of the charged particles on the peripheral edge of the substrate in which the energy of the charged particles is greater than those of the other portions. Accordingly, it is possible to reduce the damage to the substrate or the film on the substrate, and thus the resistance value of the film forming material can be suppressed from increasing. As a result, since the incidence of the charged particles on the substrate is suppressed uniformly over the entire substrate at the time of forming the film using the sputtering method, it is possible to improve the film characteristics of the film forming material formed on the substrate.

### ADVANTAGEOUS EFFECTS OF THE INVENTION

According to the present invention, since a strong magnetic field is generated above the peripheral edge of the substrate, it is possible to suppress the incidence of the charged particles on the peripheral edge of the substrate in which the energy of the charged particles is greater than those of the other portions. Accordingly, it is possible to reduce the damage to the substrate or the film on the substrate, and thus the resistance value of the film forming material can be suppressed from increasing. As a result, since the incidence of the charged particles on the substrate is suppressed uniformly over the entire substrate at the time of forming a film using the sputtering method, it is possible to improve the film characteristics of the film forming material formed on the substrate.

### BRIEF DESCRIPTION OF THE DRAWINGS

FIG. 1 is a diagram schematically illustrating the configuration of a system for manufacturing a tunnel junction element according to an embodiment of the present invention.

FIG. 2A is a perspective view of a sputtering apparatus according to the embodiment.

FIG. 2B is a side sectional view (taken along line A-A of FIG. 2A) of the sputtering apparatus according to the embodiment.

FIG. 3 is a sectional view taken along line B-B of FIG. 2A.

FIG. 4A is a side sectional view of a tunnel junction element.

FIG. 4B is a diagram schematically illustrating the configuration of an MRAM.

FIG. 5 is a sectional view corresponding to line B-B of FIG. 2A and illustrating the configuration of another sputtering apparatus.

### DESCRIPTION OF THE REFERENCE SYMBOLS

5: SUBSTRATE

23: SPUTTERING APPARATUS

62: TABLE

64: TARGET

65: PERMANENT MAGNET (MAGNETIC FIELD APPLYING DEVICE)

73: SPUTTERING GAS SUPPLY DEVICE (GAS SUPPLY DEVICE)

### BEST MODE FOR CARRYING OUT THE INVENTION

Hereinafter, a sputtering apparatus and a film forming method according to an embodiment of the present invention will be described with reference to the accompanying drawings. In the drawings referred to in the following description, the scale of the elements is properly changed so as to facilitate recognition of the elements.

### Magnetic Multilayer Film

A tunnel junction element having a TMR film as an example of a multilayer film including a magnetic layer and an MRAM having the tunnel junction element will be first described.

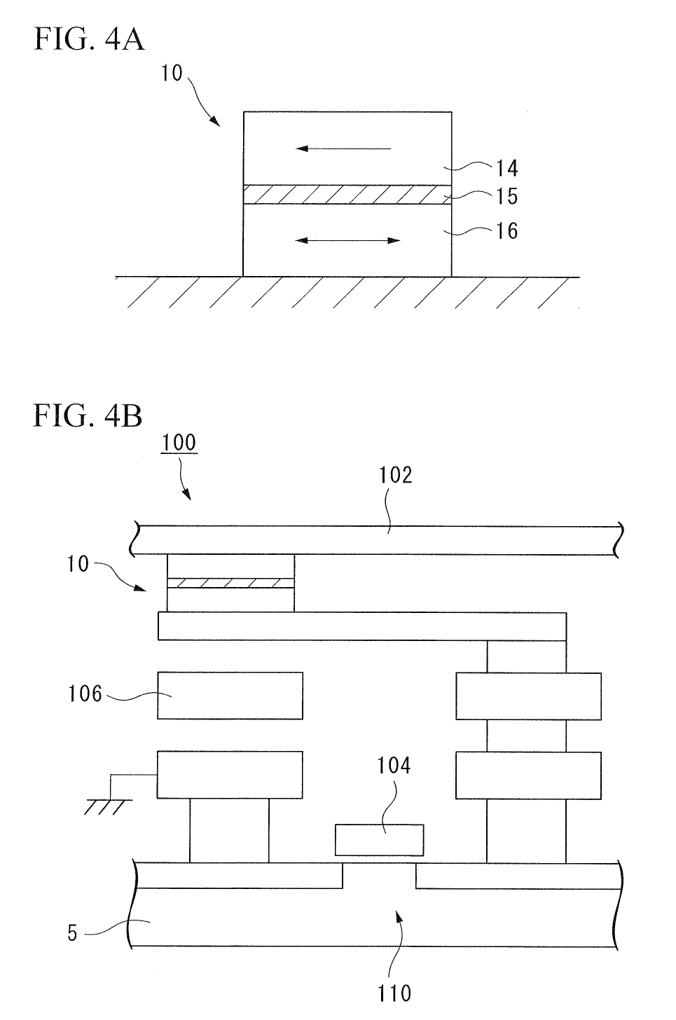

FIG. 4A is a side sectional view of a tunnel junction element.

The tunnel junction element 10 roughly includes an anti-ferromagnetic layer (not shown) formed of PtMn or IrMn, a magnetic layer (fixed layer) 14 formed of NiFe, CoFe, or CoFeB, a tunnel barrier layer 15 formed of MgO, and a magnetic layer (free layer) 16 formed of NiFe, CoFe, CoFeB, or the like. Actually, other functional layers are stacked to form a multilayer structure having about 15 layers.

FIG. 4B is a diagram schematically illustrating the configuration of an MRAM having the tunnel junction element.

In the MRAM 100, the tunnel junction elements 10 and MOSFETs 110 are arranged in a matrix on a substrate 5. The top of the tunnel junction element 10 is connected to a bit line 102 and the bottom thereof is connected to the source or drain electrode of the MOSFET 110. The gate electrode of the MOSFET 110 is connected to a reading word line 104. On the other hand, a rewriting word line 106 is disposed under the tunnel junction element 10.

In the tunnel junction element 10 shown in FIG. 4A, the magnetization direction of the magnetic layer 14 is kept in one fixed direction and the magnetization direction of the free layer 16 can be reversed. The resistance value of the tunnel junction element 10 varies depending on whether the magnetization directions of the magnetic layer 14 and the free layer 16 are parallel or inversely parallel to each other. That is, when a voltage is applied in the thickness direction of the tunnel junction element 10, the magnitude of the current flowing in the tunnel barrier layer 15 varies depending on whether the magnetization directions of the magnetic layer 14 and the free layer 16 are parallel or inversely parallel to each other (TMR effect). Therefore, by turning on the MOSFET 110 using the reading word line 104 shown in FIG. 4B and measuring the current, “1” or “0” can be read.

By supplying current to the rewriting word line 106 to generate a magnetic field around it, it is possible to reverse the magnetization direction of the free layer 16. Accordingly, it is possible to rewrite “1” or “0”.

### System for Manufacturing Tunnel Junction Element

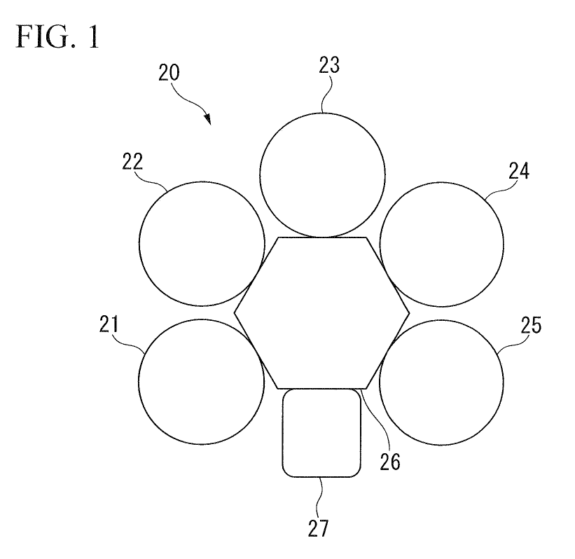

FIG. 1 is a diagram schematically illustrating a system (hereinafter, referred to as “manufacturing system”) for manufacturing a tunnel junction element according to the embodiment.

As shown in FIG. 1, the manufacturing system 20 according to the present embodiment includes plural sputtering apparatuses 21 to 24 arranged in a radial shape about a substrate feed chamber 26. The manufacturing system 20 is, for example, a cluster-type manufacturing system consistently performing film forming processes for the tunnel junction element 10.

Specifically, the manufacturing system 20 includes a substrate cassette chamber 27 holding substrates 5 having no film formed thereon, a first sputtering apparatus 21 forming an anti-ferromagnetic layer, a second sputtering apparatus 22 forming a magnetic layer (fixed layer) 14, a sputtering apparatus (third sputtering apparatus) 23 forming a tunnel barrier layer 15, a fourth sputtering apparatus 24 forming a magnetic layer (free layer) 16, and an apparatus 25 pre-processing the substrate of the tunnel junction element 10 formed by the sputtering apparatuses 21 to 24. Accordingly, the manufacturing system 20 can form a magnetic multilayer film on the substrate 5 without exposing the substrate 5 supplied to the manufacturing system 20 to air.

The first, second, and fourth sputtering apparatuses 21, 22, and 24 forming the anti-ferromagnetic layer and the magnetic layers 14 and 16 are provided with magnetic field applying devices (not shown) for giving an anisotropic magnetism property to the anti-ferromagnetic layer and the magnetic layers 14 and 16.

Here, the sputtering apparatus 23 forming the tunnel barrier layer 15, which is a sputtering apparatus according to the present embodiment, will be described in more detail.

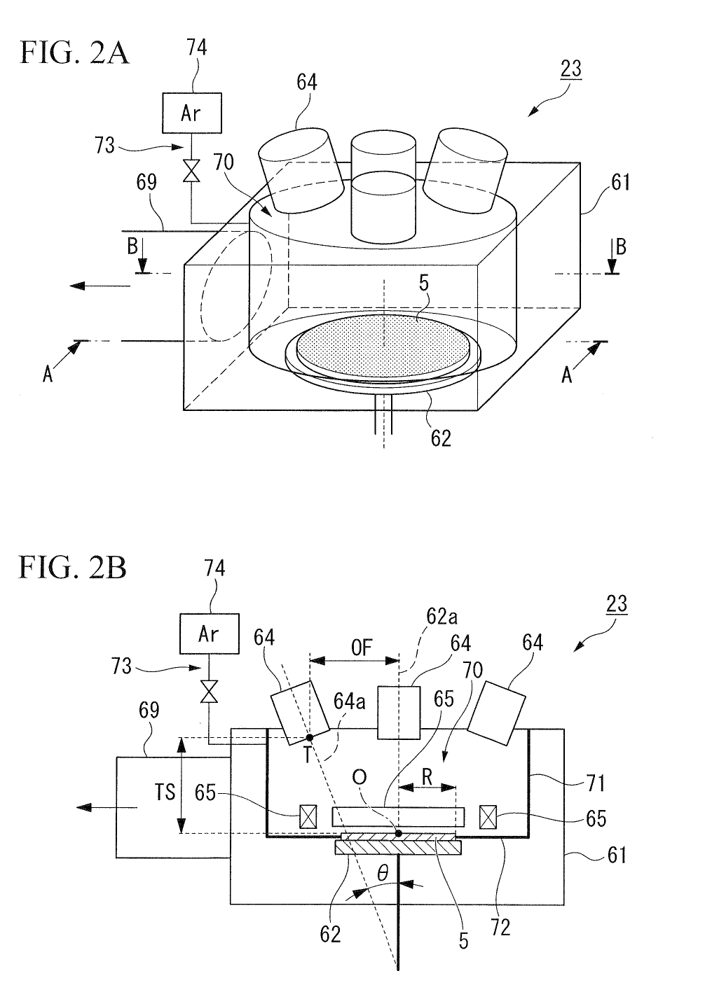

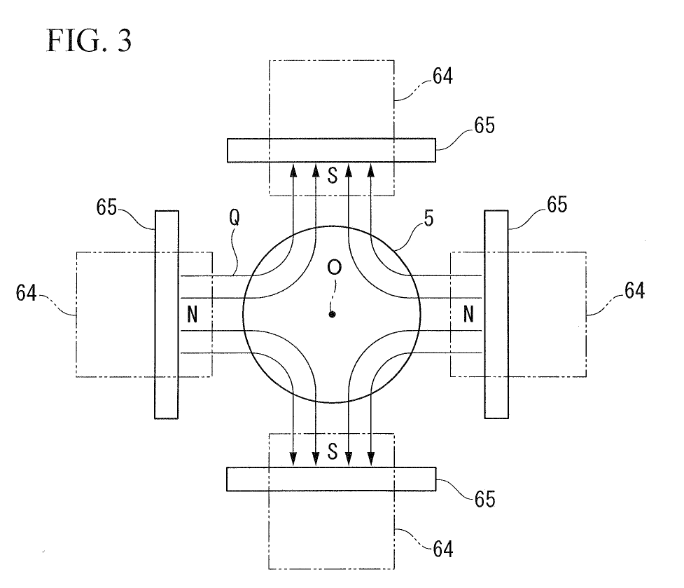

FIG. 2A is a perspective view of a sputtering apparatus according to the present embodiment. FIG. 2B is a side sectional view taken along line A-A of FIG. 2A. FIG. 3 is a plan sectional view taken along line B-B of FIG. 2A.

As shown in FIGS. 2A and 2B, the sputtering apparatus 23 includes a table 62 on which the substrate 5 is placed and targets 64, which are disposed at predetermined positions. The substrate 5 having the anti-ferromagnetic layer and the magnetic layer 14 formed thereon by the first and second sputtering apparatuses 21 and 22 is fed to sputtering apparatus 23 from the substrate feed chamber 26 via an input port not shown in the figures.

As shown in FIG. 2B, the sputtering apparatus 23 includes a chamber 61 formed in a box shape out of a metal material such as Al alloy or stainless steel. The table 62 on which the substrate 5 is placed is disposed at the center in the vicinity of the bottom of the chamber 61. The table 62 can be rotated at an arbitrary number of rotations, by a rotation mechanism not shown in the figures, with the rotation axis 62a matched with the center O of the substrate 5. The table 62 can rotate the substrate 5 placed thereon in a direction parallel to the surface of the substrate 5. In the present embodiment, a substrate of which, for example, a diameter of 200 mm is used as the substrate 5.

In the sputtering apparatus 23, a shield plate (a side shield plate 71 and a bottom shield plate 72) formed of stainless steel or the like are disposed to surround the table 62 and the targets 64. The side shield plate 71 is formed in a cylindrical shape so that the center axis corresponds to the rotation axis 62a of the table 62. The bottom shield plate 72 is disposed from the lower end of the side shield plate 71 to the peripheral edge of the table 62. The bottom shield plate 72 is parallel to the surface of the substrate 5 so that the center axis thereof corresponds to the rotation axis 62a of the table 62.

The space surrounded with the table 62, the bottom shield plate 72, the side shield plate 71, and the ceiling of the chamber 61 is a sputtering process chamber 70 (sputtering chamber) in which a sputtering process is performed on the substrate 5. The sputtering chamber 70 has an axial symmetry and the symmetric axis thereof corresponds to the rotation axis 62a of the table 62. Accordingly, it is possible to perform a uniform sputtering process on every part of the substrate 5, thereby reducing the variation in film thickness distribution.

Sputtering gas supply device (gas supply device) 73 for supplying sputtering gas is connected to the upper portion of the side shield plate 71 of the sputtering chamber 70. The sputtering gas supply device 73 introduces the sputtering gas such as argon (Ar) into the sputtering chamber 70. The sputtering gas is supplied from a sputtering gas supply source 74 disposed outside of the sputtering chamber 70. Reaction gas such as O₂ may be supplied from the sputtering gas supply device 73. An exhaust port 69 is disposed on the side surface of the chamber 61. The exhaust port 69 is connected to a vacuum pump (vacuum exhaust device) not shown in the figures.

In the peripheral edge in the vicinity of the ceiling of the chamber 61, plural (for example, four) targets 64 are arranged at a constant interval around the rotation axis 62a of the table 62 (in the peripheral direction of the substrate 5). The targets 64 are connected to an external power source (power supply) not shown and are kept in a negative potential (cathode).

A film forming material of the tunnel barrier layer 15 is disposed on the surfaces of the targets 64. A material having an insulating property is used as the film forming material. In the present embodiment, for example, MgO giving high MR or the like is used.

The targets 64 are disposed at predetermined positions relative to the substrate 5 placed on the table 62. Here, as shown in FIG. 2B, it is assumed that the distance from the rotation axis 62a of the table 62 to the peripheral edge of the substrate 5 placed on the table 62 is R. In the present embodiment, since the rotation axis 62a of the table 62 corresponds to the center O of the substrate 5, the radius of the substrate 5 is R. When the distance from the rotation axis 62a of the table 62 to the center point T of the surface of the target 64 is OF and the height from the surface of the substrate 5 placed on the table 62 to the center point T of the surface of the target 64 is TS, for example, OF=175 mm and TS 195 mm are set.

The target 64 is disposed so that the normal line (center axis) 64a passing through the center point T of the surface thereof inclines with respect to the rotation axis 62a of the substrate 5, for example, by an angle θ (about 22.5 degrees) and the normal line 64a of the target 64 and the surface of the substrate 5 intersect with each other at the peripheral edge of the substrate 5. In this case, the intersection between the normal line 64a passing through the center point T of the target 64 and the surface of the substrate 5 is located at a position separated by about 2 mm from the peripheral edge of the substrate 5, when the diameter of the substrate 5 is 200 mm.

Here, as shown in FIG. 3, between the target 64 and the substrate 5 and outside the substrate 5 in the diameter direction, plural (for example, four) permanent magnets (magnetic field applying devices) 65 are disposed along the side shield plate 71. The permanent magnets 65 are arranged at a constant interval in the peripheral direction of the substrate 5 so as to surround the substrate 5. The permanent magnets 65 are disposed so that the polarities of the surfaces facing the inside in the diameter direction of the substrate 5 are alternately arranged in the peripheral direction of the substrate 5. That is, the permanent magnets 65 are disposed so that the polarities of the adjacent permanent magnets 65 are different from each other. In addition, the permanent magnets 65 are disposed so that the polarities of the permanent magnets 65 facing each other with the substrate 5 interposed therebetween are equal to each other.

As described above, the permanent magnets 65 are arranged in the peripheral direction of the substrate 5. The targets 64 are also arranged in the peripheral direction of the substrate 5. The permanent magnets 65 and the targets 64 have the same angular positions in the peripheral direction of the substrate 5, that is, overlap with each other in a plan view. Magnetic fields are generated so that the magnetic lines of force Q extend from the N pole of one permanent magnet 65 of the adjacent permanent magnets 65 to the S pole of the other permanent magnet 65. Accordingly, the magnetic fields having a horizontal magnetic field component parallel to the surface of the substrate 5 and being along the peripheral edge of the substrate 5 are generated between the targets 64 and the substrate 5 (see arrow Q in FIG. 3). At this time, at least in the vicinity of the center O of the substrate 5, a part with a magnetic field intensity of O exists due to the overlapping of the magnetic fields generated from the permanent magnets 65.

### Film Forming Method

A film forming method using the sputtering apparatus according to the present embodiment will be described below. In the following description, a method of forming the tunnel barrier layer 15, which is performed by the sputtering apparatus 23, will be mainly described.

First, as shown in FIGS. 2A and 2B, the substrate 5 is placed on the table 62 and the table 62 is rotated at a predetermined number of rotations by the rotation mechanism. The sputtering chamber 70 is made to be in vacuum by the use of the vacuum pump and then the sputtering gas such as argon is introduced into the sputtering chamber 70 from the sputtering gas supply device 73. A voltage is applied to the targets 64 from the external power source connected to the targets 64 to generate plasma. Ions of the sputtering gas collide with the targets 64 as cathodes and atoms of the film forming material are popped out from the targets 64. The atoms of the material are attached to the substrate 5. In this way, the tunnel barrier layer 15 is formed on the surface of the substrate 5 (see FIGS. 4A and 4B). At this time, when high-density plasma is generated in the vicinity of the targets 64, it is possible to enhance the film forming speed.

As described above, in the sputtering apparatus performing a film forming process using multiple targets while rotating a substrate, an excellent film thickness distribution can be obtained, but there is a problem in that a variation in resistance value is caused on the surface of the substrate due to different film characteristics.

Specifically, in the region in the vicinity of the intersection between the axial line of the target 64 and the surface of the substrate 5, that is, in the peripheral edge of the substrate 5, since the flight distance of electrons or oxygen ions incident from the vicinity of the target 64 is small and the incidence angle on the surface of the substrate 5 is small, the energy of the incident electrons or oxygen ions is large. Accordingly, the damage to the crystal structure of the tunnel barrier layer 15 locally increases, thereby enhancing the resistance value of the tunnel barrier layer 15.

On the other hand, as it goes from the peripheral edge of the substrate 5 to the center thereof, the flight distance of the electrons or oxygen ions incident from the vicinity of the target 64 is large and the incidence angle on the surface of the substrate 5 increases, whereby the energy of the incident electrons or oxygen ions is reduced. Accordingly, the damage to the crystal structure of the tunnel barrier layer 15 decreases, thereby reducing the resistance value of the tunnel barrier layer 15 in comparison with the peripheral edge of the substrate. As a result, the variation in resistance is caused on the surface of the substrate 5, thereby deteriorating the uniformity of the film characteristic distribution of the substrate 5.

On the contrary, in the present embodiment, since the magnetic fields are generated between the substrate 5 and the targets 64 by the permanent magnets 65, the incidence of the electrons or oxygen ions on the surface of the substrate 5 is prevented.

As shown in FIG. 3, when the magnetic fields are applied by the use of the permanent magnets 65 disposed between the targets 64 and the substrate 65, the magnetic fields substantially parallel to the surface of the substrate 5 are generated to surround the substrate 5 (see arrow Q in FIG. 3). Specifically, the magnetic fields are generated so that the magnetic lines of force Q extend from the N pole of one permanent magnet 65 of the adjacent permanent magnets 65 to the S pole of the other permanent magnet 65.

At this time, on the surface of the substrate 5, the magnetic fields are concentrated on the peripheral edge of the substrate 5 and the magnetic fields are weakened as it goes from the permanent magnets 65 to the center O. As a result, a stronger magnetic field is generated on the peripheral edge of the substrate 5 so as to surround the substrate 5. The magnetic fields between the substrate 5 and the targets 64 are preferably applied to be 10 Oe or larger in the region with the strongest magnetic field, that is, in the peripheral edge of the substrate 5.

In a region where the magnetic fields are generated, when the electrons or oxygen ions, that are generated in the plasma in the vicinity of the targets 64 and fly to the substrate 5, reach the region, they are deflected in the direction perpendicular to the flight direction of the electrons or oxygen ions and the direction of the magnetic field. Particularly, since the strong magnetic fields are generated in the peripheral edge of the substrate 5 in which the amount of electrons or oxygen ions incident thereon is great, the electrons or oxygen ions with high energy flying to the peripheral edge of the substrate 5 are more reliably deflected. This is because a charged particle with an amount of charges of q is influenced by the Lorentz force F which is expressed by F=q(E+v×B). Here, E represents the electric field in the space in which the particle flies, B represents the force of the magnetic field, and v represents the velocity of the charged particles.

Here, when a magnetic field B acting in the direction perpendicular to the velocity v of the charged particle (parallel to the surface of the substrate 5) is generated, a force is applied to the charged particle in a direction perpendicular to the direction thereof. Accordingly, in the present embodiment, since the electrons or oxygen ions influenced by the Lorentz force are deflected in the direction perpendicular to the flight direction and the direction of magnetic field, the electrons or oxygen ions fly without being incident on the surface of the substrate 5.

In the present embodiment, multiple permanent magnets 65 are disposed in the outside in the diameter direction of the substrate 5 between the targets 64 and the substrate 5 so as to surround the substrate 5.

According to this configuration, since the magnetic fields are generated by the multiple permanent magnets 65 disposed to surround the substrate 5, the magnetic fields parallel to the surface of the substrate 5 are generated. Accordingly, the electrons or oxygen ions generated in plasma are subjected to the action of the Lorentz force from the generated magnetic fields and are thus deflected in the direction perpendicular to the flight direction of the electrons or oxygen ions and the direction of the magnetic fields. Particularly, when the number of permanent magnets 65 is even (for example, four), a strong magnetic field completely surrounding the substrate 5 is generated. Accordingly, it is possible to prevent the incidence of the electrons or oxygen ions on the peripheral edge of the substrate 5 where the energy of the electrons or oxygen ions is greater than those of the other regions. Therefore, since the damage to the substrate 5 or the tunnel barrier layer 15 formed on the substrate 5 can be reduced, it is possible to suppress an increase in tunnel resistance of the tunnel barrier layer 15 formed of an insulating material such as MgO.

As a result, when a large substrate with a size of 200 mm or more is used in forming a film using the sputtering method, the incidence of the electrons or oxygen ions on the substrate 5 is suppressed uniformly over the entire surface of the substrate 5 in the entire process of forming the tunnel barrier layer 15, thereby improving the in-plane uniformity as a film characteristic of the tunnel barrier layer 15 formed on the substrate 5.

Since the film forming process can be performed while rotating the substrate 5 to be parallel to the surface thereof by the use of the rotation mechanism, the film can be formed uniformly on the entire surface of the substrate 5. As a result, it is possible to accomplish the excellent uniformity in film thickness distribution, for example, of 1% or less. Since the magnetic fields generated by the permanent magnets 65 can be uniformly applied to the peripheral edge of the substrate 5, it is possible to suppress the damage to the substrate 5 in the entire process of forming the tunnel barrier layer 15 as well as in the initial growth process of forming the tunnel barrier layer 15, which is formed as a lower layer of the tunnel junction element 10, such as MgO. As a result, it is possible to maintain the film characteristics such as the crystalline properties of a very thin tunnel barrier layer 15 with a thickness of several Å to 20 Å in the entire film forming process.

In addition, since the permanent magnets 65 and the targets 64 are arranged to overlap with each other in a plan view, it is possible to generate a strong magnetic field in a region where the electrons or oxygen ions incident on the substrate 5 have large energy and to generate a weak magnetic field in a region where the electrons or oxygen ions have small energy. Accordingly, it is possible to uniformly deflect the electrons or oxygen ions incident on the substrate 5. As a result, since the incidence of the electrons or oxygen ions on the substrate 5 is uniformly suppressed over the entire substrate 5, it is possible to improve the film characteristic.

By forming the tunnel barrier layer (insulating film) 15 by the use of the sputtering apparatus 23, it is possible to prevent the electrons or oxygen ions generated in plasma from being incident on the surface of the substrate 5, thereby reducing the damage to the substrate 5. As a result, it is possible to form the tunnel barrier layer 15 with a high crystal orientation on the entire surface of the substrate 5.

While the exemplary embodiments of the present invention have been described with reference to the accompanying drawings, the present invention is not limited to the exemplary embodiments. The constituent elements and configurations described in the above embodiments are only examples and the present invention may be modified in various forms depending on design requests without departing from the technical spirit of the present invention.

For example, although it has been described in the present embodiment that the MgO film is used as the film forming material of the tunnel barrier layer of the TMR element, the film forming material is not limited thereto.

In the present embodiment, four permanent magnets 65 are arranged to surround the substrate 5 (see FIG. 3). However, the number of permanent magnets can be changed properly in design as long as the substrate is surrounded with three or more permanent magnets.

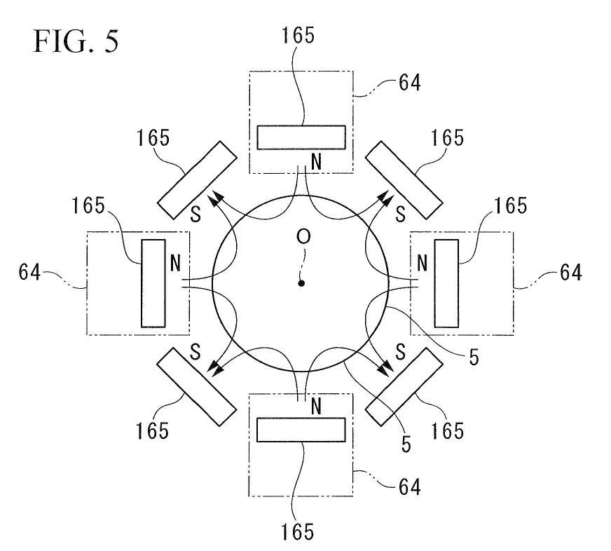

For example, as shown in FIG. 5, eight permanent magnets 165 may be disposed in the outside in the diameter direction of the substrate 5 so as to surround the substrate 5.

According to this configuration, since the intensity of magnetic field in the peripheral edge of the substrate 5 can be made to be more uniform, it is possible to efficiently deflect the electrons or oxygen ions incident on the peripheral edge of the substrate 5.

In the present embodiment, the magnetic field parallel to the substrate is generated by disposing the permanent magnets to be parallel to the side shield plate. However, the permanent magnets may be oblique about the substrate (for example, by 0 to 35 degrees), as long as they generate a magnetic field along the surface of the substrate. For example, the permanent magnets may be disposed to apply a magnetic field in the direction perpendicular to the flight direction of the electrons or oxygen ions.

### INDUSTRIAL APPLICABILITY

It is possible to provide a sputtering apparatus and a film forming method, which can improve the film characteristic by uniformly suppressing the incidence of charged particles on a substrate over the entire substrate at the time of forming a film using a sputtering method.

What is claimed is:

1. A sputtering apparatus forming a film on a surface of a substrate, comprising:
a table on which the substrate is placed;
a plurality of targets disposed so that center axes thereof incline with respect to a normal line of the substrate placed on the table; and
a plurality of magnetic field applying devices disposed between the targets and the substrate so as to surround the substrate, wherein the magnetic field applying devices generates a magnetic field, which has a horizontal magnetic field component parallel to the surface of the substrate, above the peripheral edge of the substrate.

2. The sputtering apparatus according to claim 1, wherein the number of the magnetic field applying devices is three or more.

3. The sputtering apparatus according to claim 1, further comprising a rotation mechanism rotating the table about a rotation axis parallel to the normal line of the substrate placed on the table.

4. The sputtering apparatus according to claim 1, wherein the number of the magnetic field applying devices is an even number greater than or equal to four, and the magnetic field applying devices are arranged so that the polarities of the adjacent magnetic field applying devices close to the substrate are different from each other.

5. The sputtering apparatus according to claim 1, wherein the magnetic field applying devices and the targets are disposed at the same angular positions in the peripheral direction of the substrate.

6. The sputtering apparatus according to claim 1, wherein each target contains MgO as a film forming material.

7. The sputtering apparatus according to claim 1, further comprising:
a sputtering chamber in which the table and the targets are arranged;
a vacuum exhaust device exhausting the sputtering chamber in vacuum;
a gas supply device supplying sputtering gas to the sputtering chamber; and
a power supply applying a voltage to the targets.

8. A film forming method using a sputtering apparatus comprising:
a table on which a substrate is placed;
a plurality of targets disposed so that center axes thereof incline with respect to a normal line of the substrate placed on the table; and
a plurality of magnetic field applying devices disposed between the targets and the substrate so as to surround the substrate, wherein a film forming process is performed on the surface of the substrate while applying a magnetic field, which has a horizontal magnetic field component parallel to the surface of the substrate, above the peripheral edge of the substrate.

9. The film forming method according to claim 8, wherein the sputtering apparatus includes three or more magnetic field applying devices.
